(19) United States
(12) Patent Application Publication
(10) Pub. No.: US 2011/0001117 A1
(43) Pub. Date: Jan. 6, 2011

(54) NANOSCALE WIRE-BASED MEMORY DEVICES

(75) Inventors: Charles M. Lieber, Lexington, MA (US); Yajie Dong, Cambridge, MA (US); Wei Lu, Ann Arbor, MI (US); Guihua Yu, Cambridge, MA (US); Michael MeAlphine, Lawrenceville, NJ (US)

Correspondence Address: Harvard University & Medical School;c/o Wolf, Greenfield & Sacks, P.C., 600 Atlantic Avenue, Boston, MA, 02210-2206, US

(73) Assignee: President and Fellows of Harvard College, Cambridge, MA (US)

(21) Appl. No.: 12/746,791

(22) PCT Filed: Jan. 21, 2009
(86) PCT No.: PCT/US09/00337

§ 371 Date: Sep. 13, 2010

Related U.S. Application Data
(60) Provisional application No. 61/022,497, filed on Jan. 21, 2008.
(60) Provisional application No. 61/011,919, filed on Jan. 22, 2008.

(51) Int. Cl. H01L 29/66; H01L 21/60

(52) U.S. Cl. 257/9; 438/468; 977/762; 257/E29.168; 257/E21.506

(57) ABSTRACT

The present invention generally relates to nanotechnology and sub-microelectronic devices that can be used in circuitry, and, in particular, to nanoscale wires and other nanostructures able to encode data. One aspect of the present invention is directed to a device comprising an electrical crossbar array comprising at least two crossed wires at a cross point. In some cases, at least one of the crossed wires is a nanoscale wire, and in certain instances, at least one of the crossed wires is a nanoscale wire comprising a core and at least one shell surrounding the core. For instance, the core may comprise a crystal (e.g., crystalline silicon) and the shell may be at least partially amorphous (e.g., amorphous silicon). In certain embodiments, the cross point may exhibit intrinsic current rectification, or other electrical behaviors, and the cross point can be used as a memory device. For example, in one embodiment, the cross point may exhibit a first conductance at a positive voltage, and the cross point may exhibit a second conductance at a negative voltage. Accordingly, by applying suitable voltages to the cross point, data may be stored at the cross point. Other aspects of the present invention are directed to systems and methods for making or using such devices, kits involving such devices, or the like.

### RELATED APPLICATIONS

This application claims the benefit of U.S. Provisional Patent Application Ser. No. 61/022,497, filed Jan. 21, 2008, entitled “Si/a-Si Core/Shell Nanowires as Nonvolatile Crossbar Switches,” by Lieber, et al.; and U.S. Provisional Patent Application Ser. No. 61/011,919, filed Jan. 22, 2008, entitled “Nanoscale Wire-Based Memory Devices,” by Lieber, et al., each incorporated herein by reference.

### GOVERNMENT FUNDING

Research leading to various aspects of the present invention were sponsored, at least in part, by DARPA. The U.S. Government has certain rights in the invention.

### FIELD OF INVENTION

The present invention generally relates to nanotechnology and sub-microelectronic devices that can be used in circuitry and, in particular, to nanoscale wires and other nanostructures able to encode data.

### BACKGROUND

Interest in nanotechnology, in particular sub-microelectronic technologies such as semiconductor quantum dots and nanowires, has been motivated by the challenges of chemistry and physics at the nanoscale, and by the prospect of utilizing these structures in electronic and related devices. While nanoscopic articles might be well-suited for transport of charge carriers and excitons (e.g. electrons, electron pairs, etc.) and thus may be useful as building blocks in nanoscale electronics applications, other than standard small-scale lithographic techniques, nanoelectronics is not a well-developed field. Thus there is a need in the art for new and improved articles and techniques involving nanoelectronics.

### SUMMARY OF THE INVENTION

The present invention generally relates to nanotechnology and sub-microelectronic devices that can be used in circuitry and, in particular, to nanoscale wires and other nanostructures able to encode data. The subject matter of the present invention involves, in some cases, interrelated products, alternative solutions to a particular problem, and/or a plurality of different uses of one or more systems and/or articles.

In one aspect, the invention is directed to a device. The device, according to a first set of embodiments, includes an electrical crossbar array comprising at least two crossed conductors, at least one of which is a nanoscale wire comprising a core and at least one shell. In another set of embodiments, the device includes an electrical crossbar array comprising at least two crossed wires crossing at a cross point, where the cross point exhibits intrinsic current rectification.

Another aspect of the present invention is directed to a method. In one set of embodiments, the method includes acts of providing an electrical crossbar array comprising at least two crossed conductors crossing at a cross point, causing the cross point to exhibit a first conductance by applying a positive voltage between the at least two crossed conductors, and causing the cross point to exhibit a second conductance different from the first conductance by applying a negative voltage between the at least two crossed conductors.

In yet another set of embodiments, the device includes non-volatile memory comprising a conductor in contact with a nanoscale wire comprising a core and at least one shell.

The method, according to another set of embodiments, includes acts of providing a nanoscale wire comprising a core and a shell at least partially surrounding the core, and transporting metal ions from a source of metal into at least a portion of the shell. In yet another set of embodiments, the method includes acts of providing a nanoscale wire comprising a core and a shell at least partially surrounding the core, where the shell comprises metal ions, and transporting at least some of the metal ions out of the shell.

In one set of embodiments, the method includes an act of switching a memory element of a crossbar array between at least two readable states by alternatively electrically biasing wires that cross in the array to define the element. In certain cases, the at least two crossed wires remain in electrical in the at least two readable states and during switching between the at least two readable states.

In another aspect, the present invention is directed to a method of memory storage. In one set of embodiments, the method includes acts of providing a memory storage device including a plurality of crossed conductors defining a plurality of memory storage units, applying an electrical potential between a first and a second conductor defining a first memory storage unit, thereby switching a memory state of the first memory storage unit from a first readable state to a second readable state, without moving the first and second crossed conductors relative to each other, and reading the memory state of the first memory storage unit by measuring a property associated with the first and second crossed conductors.

The present invention, in still another aspect, includes a data storage device. The data storage device includes, in one set of embodiments, an electrical crossbar array comprising at least two crossed wires defining a memory element able to be switched between at least two readable states. In some cases, the device is free of means addressing the memory element for switching the memory element between the at least two states, where the at least two crossed wires remain in electrical communication in the at least two readable states and during switching between the at least two readable states.

According to another aspect, the present invention includes an article comprising an electrical crossbar array comprising at least two crossed wires defining a memory element able to be switched between at least two readable states. In one set of embodiments, the device is free of auxiliary circuitry defining the memory element, where the at least two crossed wires remain in electrical in the at least two readable states and during switching between the at least two readable states.

In another aspect, the present invention is directed to a method of making one or more of the embodiments described herein, for example, a memory device comprising a nanoscale wire. In another aspect, the present invention is directed to a method of using one or more of the embodiments described herein, for example, a memory device comprising a nanoscale wire.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIGS. 1A-1B illustrate a nanowire switch according to one embodiment of the present invention;

FIGS. 2A-2C illustrate current vs. voltage sweeps of certain embodiments of the invention;

FIGS. 3A-3D illustrate ON state resistances of certain embodiments of the invention;

FIGS. 4A-4C illustrate write-read-erase-read cycles of one embodiment of the invention;

FIGS. 5A-5E illustrate various arrays of certain embodiments of the invention;

FIG. 6 illustrates current-voltage data of an embodiment of the invention;

FIGS. 7A-7B illustrate certain control devices of various embodiments of the invention;

FIG. 8 illustrates analysis of the data shown in FIG. 2C;

FIGS. 9A-9B illustrate an array of on a polyimide substrate, in accordance with another embodiment of the invention;

FIG. 10 shows an example of a circuit useful for controlling the current needed to reach the “ON” state, in one embodiment of the invention;

FIG. 11 shows control of the current needed to reach the “ON” state, in another embodiment of the invention; and

FIGS. 12A-12D show various metal ions used to produce different types of electrical behavior, in certain embodiments of the invention.

### DETAILED DESCRIPTION

The present invention generally relates to nanotechnology and sub-microelectronic devices that can be used in circuitry and, in particular, to nanoscale wires and other nanostructures able to encode data. One aspect of the present invention is directed to a device comprising an electrical crossbar array comprising at least two crossed wires at a cross point. In some cases, at least one of the crossed wires is a nanoscale wire, and in certain instances, at least one of the crossed wires is a nanoscale wire comprising a core and at least one shell surrounding the core. For instance, the core may comprise a crystal (e.g., crystalline silicon) and the shell may be at least partially amorphous (e.g., amorphous silicon). In certain embodiments, the cross point may exhibit intrinsic current rectification, or other electrical behaviors, and the cross point can be used as a memory device. For example, in one embodiment, the cross point may exhibit a first conductance at a positive voltage, and the cross point may exhibit a second conductance at a negative voltage. Accordingly, by applying suitable voltages to the cross point, data may be stored at the cross point. Other aspects of the present invention are directed to systems and methods for making or using such devices, kits involving such devices, or the like.

The following documents are incorporated herein by reference: U.S. patent application Ser. No. 10/196,337, filed Jul. 16, 2002, entitled “Nanoscale Wires and Related Devices,” by Lieber, et al., now U.S. Pat. No. 7,301,199, issued Nov. 27, 2007; U.S. patent application Ser. No. 10/033,369, filed Oct. 24, 2001, entitled “Nanoscopic Wire-Based Devices and Arrays,” by Lieber, et al., now U.S. Pat. No. 6,781,166, issued Aug. 24, 2004; U.S. patent application Ser. No. 10/995,075, filed Nov. 22, 2004, entitled “Nanoscale Arrays, Robust Nanostructures, and Related Devices,” by Whang, et al., published as U.S. Patent Application Publication No. 2005/0253137 on Nov. 17, 2005; and International Patent Application No. PCT/US2005/044212, filed Dec. 6, 2005, entitled “Nanoscale Wire Based Data Storage,” by Lieber, et al., published as WO 2007/044034 on Apr. 19, 2007. Also incorporated by reference are U.S. Provisional Patent Application Ser. No. 61/022,497, filed Jan. 21, 2008, entitled “Si/a-Si Core/Shell Nanowires as Nonvolatile Crossbar Switches,” by Lieber, et al.; and U.S. Provisional Patent Application Ser. No. 61/011,919, filed Jan. 22, 2008, entitled “Nanoscale Wire-Based Memory Devices,” by Lieber, et al.

One aspect of the present invention is directed to an electrical crossbar array comprising at least two crossed conductors. In some cases, the conductors may be in physical contact with each other. One or both of the crossed conductors may be a nanoscale wire. The crossbar array can be of a variety of configurations, including any number of parallel conductors in either dimension, such as a 1×4 array, a 4×4 array, a 1×8 array, a 8×8 array, a 8×16 array, a 16×16 array, a 64×64 array, a 256×256 array, etc. The array can include contact electrodes in electrical contact with various wires. The contact electrode may be formed of any suitable material, e.g., a metal such as nickel may be deposited onto the conductors.

The conductors may be formed of any suitable material able to at least partially conduct electricity, for instance, a metal (e.g., gold, aluminum, copper, silver, etc.) or a semiconductor (e.g., silicon), such as those described herein. In one set of embodiments, one or more of the conductors contained within the array may comprise a nanoscale wire, for instance, a nanowire.

In one set of embodiments, one or more of the conductors may be a nanowire comprising a core and at least one shell at least partially surrounding the core. The core and the shell may be formed of the same or different materials. For example, the core may comprise crystalline silicon while the shell may comprise amorphous silicon, such that the core and the shell can be distinguished on the basis of crystallinity, e.g., using techniques such as TEM, HRTEM, or the like.

Surprisingly, a nanoscale wire comprising a core and at least one shell, when crossed with a conductor, may exhibit intrinsic current rectification. That is, the cross point where the nanoscale wire contacts the conductor may exhibit intrinsic rectification properties, where the cross point exhibits a first conductance at a first voltage (e.g., a positive voltage) and a second conductance at a second voltage (e.g., a negative voltage). The change in conductance between the first and second voltages may be quite large in some cases. In some cases, there is a threshold voltage where the conductance changes rapidly from a first value to a second value over a small range, e.g., within about 0.5 V or about 0.3 V. In some embodiments, the conductance within the cross point may be controlled by controlling the applied current. For instance, relatively higher currents may yield cross points having relatively lower resistances, or vice versa. Thus, the cross point may be activated, e.g., to an “ON” state, using different amounts of applied currents. This may be useful, for example, in high density multistate memory applications. A non-limiting example of such a system is discussed in Example 2, where a resistor is used to control the amount of current needed to reach the “ON” state.

In certain cases, the cross point may also exhibit hysteresis. For instance, the conductance may change rapidly going from the first voltage to the second voltage, but may change slowly going from the second voltage back to the first voltage, such that the conductance changes in each direction do not coincide.

Without wishing to be bound by any theory, it is believed that the conductance states may be altered due to the movement of ions, such as metal ions, between the conductor and the shell of the nanoscale wire. The ions may be produced by the conductor in some cases. The presence (or absence) of ions within the shell may alter the conductance of the shell, and thereby alter the conductance of the cross point where the conductor and the core/shell nanoscale wire come into contact. Ions may be transported into the shell by the application of a first voltage (e.g., a positive voltage), thereby increasing the conductance of the shell, and the ions may be transported out of the shell by the application of a second voltage (e.g., a negative voltage), thereby decreasing the conductance of the shell. In some cases, the shell and the conductor are in physical contact with each other, facilitating the movement of ions from the conductor to the shell (or vice versa). However, in other cases, the shell and the conductor may be separated by another material, e.g., an ion-conductive material. In addition, in the absence of a voltage, the ions may not substantially move from the shell; accordingly, one embodiment of the invention is directed to a non-volatile memory device.

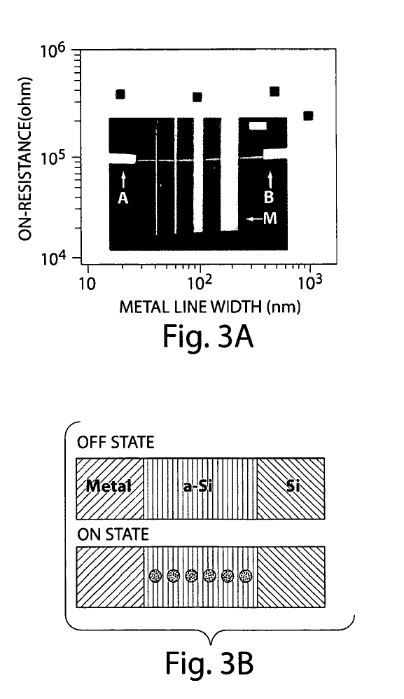

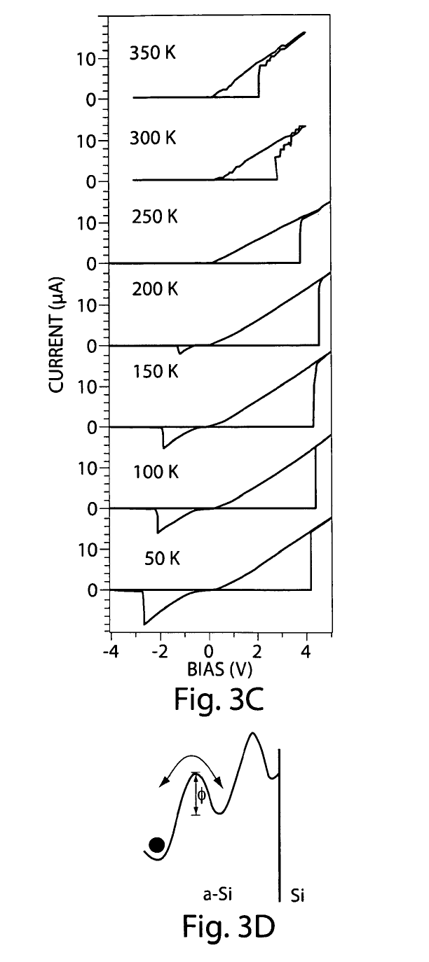

In some cases, other types of switching or electrical behavior may be produced in such systems. For instance, in one set of embodiments, different metal ions may be used to produce different behaviors, depending on the mobility of the metal ions. As an example, silver ions have a relatively high degree of mobility, and may be transported into and out of the shell, as discussed above. In another set of embodiments, however, aluminum ions may be used, which have a relatively lower degree of mobility, and can be transported into the shell, but cannot be as readily transported out of the shell by application of a second voltage. Under such circumstances, the device may be useful as a WORM (“write once read many”) device. As another example, if gold or copper ions are used, the device may behave as a non-rectified switch. As an illustrative example, in FIG. 3B, upper panel, an “OFF” state may be defined by a metal conductor, and a nanoscale wire comprising a core and a shell, where the core comprises crystalline silicon and the shell comprises amorphous silicon. The “ON” state may be created when metal ions flow from the metal into the amorphous silicon region, as is shown in FIG. 3B, lower panel, which can alter the conductivity of the amorphous silicon region and hence the conductivity of the cross point. In some cases, enough metal ions may enter the amorphous silicon region (e.g., to an imposed voltage) such that a metal “filament” is created in the amorphous silicon region. The process can also be reversed by applying voltage having the opposite polarity, thereby causing at least some of the metal ions within the amorphous silicon region to leave, thereby altering the conductivity of the amorphous silicon region.

Such properties may be useful within a memory device. For instance, by controlling the voltages and determining conductances, a memory state (e.g., “ON” or “OFF”) may be determined within the cross point. The “OFF” and “ON” states can be read by measuring resistance or conductance of the cross point. In one embodiment, a difference between the conductances between two crossed conductors is sufficient to differentiate between the “ON” and “OFF” position.

As a specific, non-limiting example, a first conductance state can be assigned “ON” and a second conductance state can be assigned “OFF” It should be noted that, as used herein, the term “bit” or “bits” is used relative to data and typically has two states, often referred to as “0” and “1”; the term “bit” or “bits” as used to measure information content in an information theory sense (for example, when a′computer file is mathematically “compressed” to reduce the file size, such that each “bit” of data is thereby used to encode multiple pieces of information) is not used herein.

Thus, a device of the invention may include an array of cross points whose conductances can be independently controlled. As an example, in one set of embodiments, a cross point may be set at a first conductance state (e.g., to encode a bit of information, for example, “ON”) by applying voltages to the cross point that has an intensity and/or a duration at least sufficient to turn the conductance state to “ON.” Thus, according to this embodiment, if the cross point was previously at the “OFF” conductance state, the cross point is now in the “ON” state; if the cross point was previously in the “ON” state, it remains in the “ON” state. Relatively low “writing” voltages may be used in some cases. In one set of embodiments, voltages having a magnitude (i.e., ignoring sign) of at least about 2 V, at least about 2.5 V, at least about 3 V, or at least about 3.5 V may be used to alter the conductance state.

In one embodiment, a voltage is created by creating a potential difference between an electrode or other probe positioned in contact or at least proximate to the conductors defining the cross point, e.g., in a cross point defined by a conductor and a core/shell nanoscale wire, a voltage may be created between the core of the nanoscale wire and the conductor. As an example, a voltage may be applied to a first conductor while a voltage of the opposite sign is applied to the second conductor, or a relatively larger voltage may be applied to the first conductor while a relatively smaller voltage is applied to the second conductor or the second conductor is grounded. Similarly, the cross point may be set to the “OFF” conductance state by applying a voltage to the cross point having an intensity and/or a duration at least sufficient to cause the cross point to switch to the “OFF” state, for example, by applying voltages similar to those described above (e.g., having opposite sign).

The conductance state of the cross point may be determined using any suitable technique. For instance, by simply measuring the conductance or resistance between the first and second conductors defining the cross point, the conductance state of the cross point (e.g., being “ON” or “OFF”) may be determined. In certain instances, relatively low “reading” voltages may be used to determine the conductance state, due to the nanoscopic nature of the wire. The reading voltage may be selected such that it is below the “writing” voltage, e.g., the voltage required to alter the conductivity of the cross point from one state to another. As discussed above, in some cases, there is a threshold voltage where the conductance changes rapidly from a first value to a second value over a small range, e.g., within about 0.5 V or about 0.3 V. The “reading” voltage may be selected to be below this value, while the “writing” voltage may be selected to be above this value, in some embodiments.

For example, in one set of embodiments, voltages having a magnitude (i.e., ignoring sign) of less than about 5 V, less than about 3 V, less than about 2.5 V, less than about 2 V, less than about 1.8 V, less than about 1.6 V, less than 1.4 V, less than about 1.2 V, less than about 1 V, less than about 0.8 V, or less than about 0.5 V may be used to determine the conductance state. Additionally, in other embodiments, the read/write voltage ratio may also be kept relatively low. For example, the ratio between the reading voltage and the writing voltage may be less than about 1:10, less than about 1:5, less than about 1:3, less than about 1:2.5, less than about 1:2, less than about 1:1.8, less than about 1:1.6, less than about 1:1.5, less than about 1:1.4, less than about 1:1.3, less than about 1:1.2, or less than about 1:1.1. In some embodiments, different ratios of read/write voltages may be used for different portions of the nanoscale wire.

If an array comprises more than one cross point, each cross point may be independently determined, and/or combinations of portions may be determined in some cases by applying suitable voltages and/or currents to the appropriate conductors defining the cross point of interest. For instance, a nanoscale wire having a core and a shell may be positioned across multiple conductors, and each cross point where the nanoscale wire contacts the conductor may define a memory location. The conductors may be spaced such that conductance states at one cross point (e.g., caused by ion flow) do not significantly affect conductance states at other cross points.

Thus, one aspect of the invention provides devices comprising any of the nanoscale wire or nanostructure embodiments described herein, including memory devices and/or devices comprising transistors, switches, or the like. Some devices may include one, or more than one, of the nanoscale wire embodiments described herein.

In one set of embodiments, a nonvolatile memory is provided. An array of the invention may be used to encode one, or more than one, bit of data, and the array may be able to retain the data even in the absence of power. In some cases, an array of nanoscale wires may be used as nonvolatile memory. In certain embodiments, a relatively high density of memory elements can be achieved. For example, in some cases, the device may comprise an array of memory elements, each having an area of less than about 100 nm²/bit, less than about 75 nm²/bit, less than about 50 nm²/bit, less than about 30 nm²/bit, less than about 25 nm²/bit, less than about 20 nm²/bit, less than about 15 nm²/bit, less than about 10 nm²/bit, less than about 8 nm²/bit, less than about 6 nm²/bit, or less than about 4 nm²/bit.

In one embodiment, an array of memory elements can be assembled using one or more nanoscale wires of the invention, crossed with one or more electrodes (e.g., as described herein). The electrodes may contact single nanoscale wires, or in some cases, the electrodes may contact more than one nanoscale wire, for example. By systematically controlling the potential of each of the nanoscale wires and each of the electrodes, specific voltages may be made to appear at any desired location or locations within the array, which can be used to read and/or write data to those locations, using techniques similar to those previously described. Thus, the intersection between a nanoscale wire and an electrode may be able to encode a bit of data. Those of ordinary skill in the art, with the benefit of the present disclosure, will be able to identify suitable systems and methods for using an array comprising rows and columns for storing and accessing bits of data at the intersections of the rows and columns.

Another aspect of the invention provides for the fabrication of any of the embodiments described herein. Techniques useful for fabricating nanoscale wires include, but are not limited to, vapor phase reactions (e.g., chemical vapor deposition (“CVD”) techniques such as metal-catalyzed CVD techniques, catalytic chemical vapor deposition (“C-CVD”) techniques, organometallic vapor phase deposition-MOCVD techniques, atomic layer deposition, chemical beam epitaxy, etc.), solution phase reactions (e.g., hydrothermal reactions, solvothermal reactions), physical deposition methods (e.g., thermal evaporation, electron-beam evaporation, laser ablation, molecular beam epitaxy), vapor-liquid-solid (“VLS”) growth techniques, laser catalytic growth (“LCG”) techniques, surface-controlled chemical reactions, or the like, for instance, as disclosed in Ser. No. 10/196,337, entitled, “Nanoscale Wires and Related Devices,” filed Jul. 16, 2002, published as Publication No. 2003/0089899 on May 15, 2003, incorporated herein by reference. As a non-limiting example, if a nanoscale wire having a core/shell arrangement is to be fabricated, the core may be fabricated using one of these techniques, and one or more shells may be at least partially coated on at least a portion of the core, for example, using CVD techniques, LCG techniques, atomic layer deposition, or the like.

The conductors may be either grown in place or deposited after growth. For instance, the conductors may be grown on a substrate using techniques such as photolithography, e.g., using submicron photolithography, extreme-UV lithography or nanoimprint lithography.

In some embodiments, the invention provides a method involving forming a nanoscopic wire on a surface in a pattern dictated by a mechanically patterned surface or by gas flow. Assembly, or controlled placement of the conductors on surfaces after growth may be performed by aligning conductors using an electrical field. An electrical field may be generated between electrodes. The conductors may be positioned between the electrodes (optionally flowed into a region between the electrodes in a suspending fluid), and may align in the electrical field, thereby spanning the distance between and contact each of the electrodes.

In another arrangement, individual contact points may be arranged in opposing relation to each other. The individual contact points may be tapered to form points directed towards each other. An electric field may be generated between such points that will attract a single nanoscopic wire to span the distance between the points, forming a pathway for electronic communication between the points. Thus, individual nanoscopic wires may be assembled between individual pairs of electrical contacts. Crossed-wire arrangements, including multiple crossings (multiple parallel wires in a first direction crossed by multiple parallel wires in a perpendicular or approximately perpendicular second direction) can readily be formed by first positioning contact points (electrodes) at locations where opposite ends of the crossed wires desirably will lie. Electrodes, or contact points, may be fabricated via any suitable microfabrication techniques, such as the ones described herein.

These assembly techniques can be substituted by, or complemented with, a positioning arrangement involving positioning a fluid flow directing apparatus to direct a fluid that may contain suspended conductors toward and in the direction of alignment with locations at which conductors are desirably positioned. A conductor solution may be prepared as follows. After the conductors are synthesized, they are transferred into a solvent (e.g., ethanol), and then may be sonicated for several seconds to several minutes to obtain a stable suspension.

Another arrangement involves forming surfaces including regions that selectively attract conductors surrounded by regions that do not selectively attract them. For example, —NH₂ can be presented in a particular pattern at a surface, and that pattern will attract conductors or nanoscale wires having surface functionality attractive to amines.

Surfaces can be patterned using known techniques such as electron-beam patterning, “soft-lithography” such as that described in International Patent Publication No. WO 96/29629, published Jul. 26, 1996, or U.S. Pat. No. 5,512,131, issued Apr. 30, 1996, each of which is incorporated herein by reference in its entirety for all purposes. Additional techniques are described in U.S. Patent Application Ser. No. 60/142,216, filed Jul. 2, 1999, by Lieber, et al., incorporated herein by reference in its entirety for all purposes. Fluid flow channels can be created at a size scale advantageous for placement of conductors on surfaces using a variety of techniques such as those described in International Patent Publication No. WO 97/33737, published Sep. 18, 1997, and incorporated herein by reference in its entirety for all purposes. Other techniques include those described in U.S. patent application Ser. No. 09/578,589, filed May 25, 2000, and incorporated herein by reference in its entirety for all purposes.

For example, one such technique for creating a fluid flow channel using a polydimethylsiloxane (PDMS) mold. Channels may be created and applied to a surface, and a mold may be removed and re-applied in a different orientation to provide a cross flow arrangement or different arrangement. The flow channel arrangement can include channels having a smallest width of less than about 1 mm, preferably less than about 0.5 mm, more preferably less than about 200 μm or less. Such channels are easily made by fabricating a master by using photolithography and casting PDMS on the master. Larger-scale assembly may be possible as well. The area that can be patterned with the arrays may be defined only by the feature of the channel which can be as large as desired.

The assembly of conductors onto substrate and electrodes may also be assisted using bimolecular recognition in certain embodiments, for example, by immobilizing one biological binding partner on a conductor surface and the other one on substrate or electrodes using physical adsorption or covalently linking. Bio-recognition techniques suitable for use in the present invention may include DNA hybridization, antibody-antigen binding, biotin-avidin, biotin-streptavidin binding, and the like.

Another technique which may be used to direct the assembly of conductors into a device is by using “SAMs,” or self-assembled monolayers. The SAMs may be chemically patterned in certain embodiments. In one example of patterning SAMs for directed assembly of nanoscopic scale circuitry using conductors of the present invention, atomic force microscopy (AFM) may be used to write, at high resolution, a pattern in a SAM, after which the SAM may then be removed. The pattern may be, for example, a linear or a parallel array, or a crossed array of lines.

In another embodiment, microcontact printing may be used to apply patterned SAMs to a substrate. Open areas in the patterned surface (i.e., the SAM-free linear region between linear SAM) may be filled, for example, with an amino-terminated SAM that may interact in a highly specific manner with a conductor such as a nanowire. The result may be a patterned SAM, on a substrate, that includes linear SAM portions separated by a line of amino-terminated SAM material. Any desired pattern may be formed where regions of the amino-terminated SAM material corresponds to regions at which wire deposition may be desired. The patterned surface may then be dipped into a suspension of conductors, e.g., nanowires, and may be rinsed to create an array of conductors. Where nanowires are used, an organic solvent such as dimethyl formamide may be used to create the suspension of nanowires. Suspension and deposition of other nanoscopic-scale wires may be achieved with solvents well-known to those of ordinary skill in the art.

Any of a variety of substrates and SAM-forming material can be used along with microcontact printing techniques, such as those described in international patent publication WO 96/29629 of Whitesides, et al., published Jun. 26, 1996 and incorporated herein by reference in its entirety for all purposes. Patterned SAM surfaces may be used to direct a variety of conductors, nanoscopic wires, or nanoscopic-scale electronic elements. SAM-forming material can be selected, with suitable exposed chemical functionality, to direct assembly of a variety of electronic elements. Electronic elements, including nanowires, can be chemically tailored to be attracted specifically to specific, predetermined areas of a patterned SAM surface. Suitable functional groups include, but are not limited to SH, NH₃, and the like. Nanowires are particularly suitable for chemical functionalization on their exterior surfaces, as is well known.

Chemically patterned surfaces other than SAM-derivitized surfaces can be used, and many techniques for chemically patterning surfaces are known. Suitable exemplary chemistries and techniques for chemically patterning surfaces are described in, among other places, International Patent Publication Serial No. WO 97/34025 of Hidber, et al., entitled, “Microcontact Printing of Catalytic Colloids,” and U.S. Pat. Nos. 3,873,359; 3,873,360; and 3,900,614, each by Lando, all of these documents incorporated herein by reference in their entirety for all purposes. Another example of a chemically patterned surface may be a micro-phase separated block copolymer structure. These structures provide a stack of dense lamellar phases. A cut through these phases reveals a series of “lanes” wherein each lane represents a single layer. The block copolymer may typically be an alternating block and can provide varying domains by which to dictate growth and assembly of a nanoscopic wire. Additional techniques are described in International Patent Application Serial No. PCT/US00/18138 filed Jun. 30, 2000, by Lieber, et al., incorporated herein by reference in its entirety for all purposes.

In still another aspect, a device of the invention may include a conductor, such as a nanoscale wire, positioned proximate the surface of a substrate, i.e., the nanoscale wire may be positioned within about 50 nm, about 25 nm, about 10 nm, or about 5 nm of the substrate. In some cases, the proximate nanoscale wire may contact at least a portion of the substrate. In one embodiment, the substrate comprises a semiconductor and/or a metal. Non-limiting examples include Si, Ge, GaAs, etc. Other suitable semiconductors and/or metals are described above with reference to nanoscale wires. In certain embodiments, the substrate may comprise a nonmetal/nonsemiconductor material, for example, a glass, a plastic or a polymer, a gel, a thin film, etc. Non-limiting examples of suitable polymers that may form or be included in the substrate include polyethylene, polypropylene, poly(ethylene terephthalate), polydimethylsiloxane, or the like.

In certain embodiments, the substrate may be at least partially and in certain such embodiments may be substantially transparent. As used herein, a “substantially transparent” material is a material that allows electromagnetic radiation to be transmitted through the material without significant scattering, i.e., at least a portion of the radiation incident on the material passes through the material unaltered. In some cases, the material is substantially transparent to incident electromagnetic radiation ranging from the infrared to ultraviolet ranges (including visible light). The substantially transparent material may be able to transmit electromagnetic radiation in some cases such that at least a portion of the radiation incident on the material passes through the material unaltered, and in some embodiments, at least about 50%, in other embodiments at least about 75%, in other embodiments at least about 80%, in still other embodiments at least about 90%, in still other embodiments at least about 95%, in still other embodiments at least about 97%, and in still other embodiments at least about 99% of the incident radiation is able to pass through the material unaltered. Suitable non-limiting examples of transparent materials include glasses, certain polymers, etc.

In certain embodiments, the substrate may be a non-planar or a curved surface (i.e., a surface that can be characterized as having a radius of curvature). In certain embodiments, the substrate may be a flexible substrate, i.e., a substrate able to bend or flex. For example, a flexible substrate may be bent or distorted by a volumetric displacement of at least about 5%, 10%, or 20% (relative to the undisturbed volume), without causing cracks and/or breakage of the substrate, i.e., the substrate can be distorted such that 5%, 10%, or 20% of the mass of the substrate has been moved outside the original surface perimeter of the substrate. Non-limiting examples of flexible substrates include polymers, fibers, gels, etc. In some cases, the flexible substrate may be present in an article that is robust, for example, able to sustain typical use (e.g., being moved, carried, dropped, etc.). For example, the substrate may be included within a wearable article, for example, an article of clothing or an accessory.

The following definitions will aid in the understanding of the invention. Certain devices of the invention may include wires or other components of scale commensurate with nanometer-scale wires, which includes nanotubes and nanowires. In some embodiments, however, the invention comprises articles that may be greater than nanometer size (e.g., micrometer-sized). As used herein, “nanoscopic-scale,” “nanoscopic,” “nanometer-scale,” “nanoscale,” the “nano-” prefix (for example, as in “nanostructured”), and the like generally refers to elements or articles having widths or diameters of less than about 1 micrometer, and less than about 100 nm in some cases. In all embodiments, specified widths can be a smallest width (i.e. a width as specified where, at that location, the article can have a larger width in a different dimension), or a largest width (i.e. where, at that location, the article has a width that is no wider than as specified, but can have a length that is greater).

The term “plurality,” as used herein, means two or more. A “set” of items may include one or more of such items.

The term “fluid” generally refers to a substance that tends to flow and to conform to the outline of its container. Typically, fluids are materials that are unable to withstand a static shear stress. When a shear stress is applied to a fluid, it experiences a continuing and permanent distortion. Typical fluids include liquids and gases, but may also include free-flowing solid particles, viscoelastic fluids, and the like.

As used herein, a “wire” generally refers to any material having a conductivity of or of similar magnitude to any semiconductor or any metal, and in some embodiments may be used to connect two electronic components such that they are in electronic communication with each other. For example, the terms “electrically conductive” or a “conductor” or an “electrical conductor” when used with reference to a “conducting” wire or a nanoscale wire, refers to the ability of that wire to pass charge. Typically, an electrically conductive nanoscale wire will have a resistivity comparable to that of metal or semiconductor materials, and in some cases, the electrically conductive nanoscale wire may have lower resistivities, for example, a resistivity lower than about 10⁻³ Ohm m, lower than about 10⁻⁴ Ohm m, or lower than about 10⁻⁶ Ohm m or 10⁻⁷ Ohm m.

A “nanoscopic wire” (also known herein as a “nanoscopic-scale wire” or “nanoscale wire”) generally is a wire, that at any point along its length, has at least one cross-sectional dimension and, in some embodiments, two orthogonal cross-sectional dimensions less than 1 micron, less than about 500 nm, less than about 200 nm, less than about 150 nm, less than about 100 nm, less than about 70, less than about 50 nm, less than about 20 nm, less than about 10 nm, or less than about 5 nm. In other embodiments, the cross-sectional dimension can be less than 2 nm or 1 nm. In one set of embodiments, the nanoscale wire has at least one cross-sectional dimension ranging from 0.5 nm to 100 nm or 200 nm. In some cases, the nanoscale wire is electrically conductive. In some embodiments, the nanoscale wire is cylindrical. In other embodiments, however, the nanoscale wire can be faceted, i.e., the nanoscale wire may have a polygonal cross-section. Where nanoscale wires are described having, for example, a core and a shell, the above dimensions generally relate to those of the core. The cross-section of a nanoscopic wire may be of any arbitrary shape, including, but not limited to, circular, square, rectangular, annular, polygonal, or elliptical, and may be a regular or an irregular shape. The nanoscale wire may be solid or hollow. Any nanoscale wire can be used in any of the embodiments described herein, including carbon nanotubes, molecular wires (i.e., wires formed of a single molecule), nanorods, nanowires, nanowhiskers, organic or inorganic conductive or semiconducting polymers, and the like, unless otherwise specified. Other conductive or semiconducting elements that may not be molecular wires, but are of various small nanoscopic-scale dimensions, can also be used in some instances, e.g. inorganic structures such as main group and metal atom-based wire-like silicon, transition metal-containing wires, gallium arsenide, gallium nitride, indium phosphide, germanium, cadmium selenide, etc. A wide variety of these and other nanoscale wires can be grown on and/or applied to surfaces in patterns useful for electronic devices in a manner similar to techniques described herein involving the specific nanoscale wires used as examples, without undue experimentation. The nanoscale wires, in some cases, may be formed having dimensions of at least about 1 micrometer, at least about 3 micrometers, at least about 5 micrometers, or at least about 10 micrometers or about 20 micrometers in length, and can be less than about 100 nm, less than about 80 nm, less than about 60 nm, less than about 40 nm, less than about 20 nm, less than about 10 nm, or less than about 5 nm in thickness (height and width). The nanoscale wires may have an aspect ratio (length to thickness) of greater than about 2:1, greater than about 3:1, greater than about 4:1, greater than about 5:1, greater than about 10:1, greater than about 25:1, greater than about 50:1, greater than about 75:1, greater than about 100:1, greater than about 150:1, greater than about 250:1, greater than about 500:1, greater than about 750:1, or greater than about 1000:1 or more in some cases.

A “nanowire” (e.g. comprising silicon and/or another semiconductor material) is a nanoscopic wire that is typically a solid wire, and may be elongated in some cases. Preferably, a nanowire (which is abbreviated herein as “NW”) is an elongated semiconductor, i.e., a nanoscale semiconductor. A “non-nanotube nanowire” is any nanowire that is not a nanotube. In one set of embodiments of the invention, a non-nanotube nanowire having an unmodified surface can be used in any arrangement of the invention described herein in which a nanowire or nanotube can be used.

As used herein, a “nanotube” (e.g. a carbon nanotube) is a nanoscopic wire that is hollow, or that has a hollowed-out core, including those nanotubes known to those of ordinary skill in the art. “Nanotube” is abbreviated herein as “NT.” Nanotubes are used as one example of small wires for use in the invention and, in certain embodiments, devices of the invention include wires of scale commensurate with nanotubes.

As used herein, an “elongated” article (e.g. a semiconductor or a section thereof) is an article for which, at any point along the longitudinal axis of the article, the ratio of the length of the article to the largest width at that point is greater than 2:1.

As used herein, a “width” of an article is the distance of a straight line from a point on a perimeter of the article, through the center of the article, to another point on the perimeter of the article. As used herein, a “width” or a “cross-sectional dimension” at a point along a longitudinal axis of an article is the distance along a straight line that passes through the center of a cross-section of the article at that point and connects two points on the perimeter of the cross-section. The “cross-section” at a point along the longitudinal axis of an article is a plane at that point that crosses the article and is orthogonal to the longitudinal axis of the article. The “longitudinal axis” of an article is the axis along the largest dimension of the article. Similarly, a “longitudinal section” of an article is a portion of the article along the longitudinal axis of the article that can have any length greater than zero and less than or equal to the length of the article. Additionally, the “length” of an elongated article is a distance along the longitudinal axis from end to end of the article.

As used herein, a “cylindrical” article is an article having an exterior shaped like a cylinder, but does not define or reflect any properties regarding the interior of the article. In other words, a cylindrical article may have a solid interior, may have a hollowed-out interior, etc. Generally, a cross-section of a cylindrical article appears to be circular or approximately circular, but other cross-sectional shapes are also possible, such as a hexagonal shape. The cross-section may have any arbitrary shape, including, but not limited to, square, rectangular, or elliptical. Regular and irregular shapes are also included.

As used herein, an “array” of articles (e.g., nanoscopic wires) comprises a plurality of the articles, for example, a series of aligned nanoscale wires, which may or may not be in contact with each other. As used herein, a “crossed array” or a “crossbar array” is an array where at least one of the articles contacts either another of the articles or a signal node (e.g., an electrode).

Many nanoscopic wires as used in accordance with the present invention are individual nanoscopic wires. As used herein, “individual nanoscopic wire” means a nanoscopic wire free of contact with another nanoscopic wire (but not excluding contact of a type that may be desired between individual nanoscopic wires, e.g., as in a crossbar array). For example, an “individual” or a “free-standing” article may, at some point in its life, not be attached to another article, for example, with another nanoscopic wire, or the free-standing article may be in solution. This is in contrast to nanotubes produced primarily by laser vaporization techniques that produce materials formed as ropes having diameters of about 2 nm to about 50 nm or more and containing many individual nanotubes (see, for example, Thess, et al., “Crystalline Ropes of Metallic Carbon Nanotubes,” Science, 273:483-486 (1996)). This is also in contrast to conductive portions of articles which differ from surrounding material only by having been altered chemically or physically, in situ, i.e., where a portion of a uniform article is made different from its surroundings by selective doping, etching, etc. An “individual” or a “free-standing” article is one that can be (but need not be) removed from the location where it is made, as an individual article, and transported to a different location and combined with different components to make a functional device such as those described herein and those that would be contemplated by those of ordinary skill in the art upon reading this disclosure.

In some embodiments, at least a portion of a nanoscopic wire may be a bulk-doped semiconductor. As used herein, a “bulk-doped” article (e.g. an article, or a section or region of an article) is an article for which a dopant is incorporated substantially throughout the crystalline lattice of the article, as opposed to an article in which a dopant is only incorporated in particular regions of the crystal lattice at the atomic scale, for example, only on the surface or exterior. For example, some articles such as carbon nanotubes are typically doped after the base material is grown, and thus the dopant only extends a finite distance from the surface or exterior into the interior of the crystalline lattice. It should be understood that “bulk-doped” does not define or reflect a concentration or amount of doping in a semiconductor, nor does it necessarily indicate that the doping is uniform. In particular, in some embodiments, a bulk-doped semiconductor may comprise two or more bulk-doped regions. Thus, as used herein to describe nanoscopic wires, “doped” refers to bulk-doped nanoscopic wires, and, accordingly, a “doped nanoscopic (or nanoscale) wire” is a bulk-doped nanoscopic wire. “Heavily doped” and “lightly doped” are terms the meanings of which are clearly understood by those of ordinary skill in the art. In some cases, one or more regions may comprise a single monolayer of atoms (“delta-doping”). In certain cases, the region may be less than a single monolayer thick (for example, if some of the atoms within the monolayer are absent). As a specific example, the regions may be arranged in a layered structure within the nanoscale wire, and one or more of the regions may be delta-doped or partially delta-doped.

As used herein, the term “Group,” with reference to the Periodic Table, is given its usual definition as understood by one of ordinary skill in the art. For instance, the Group II elements include Mg and Ca, as well as the Group II transition elements, such as Zn, Cd, and Hg. Similarly, the Group III elements include B, Al, Ga, In and Tl; the Group IV elements include C, Si, Ge, Sn, and Pb; the Group V elements include N, P, As, Sb and Bi; and the Group VI elements include O, S, Se, Te and Po. Combinations involving more than one element from each Group are also possible. For example, a Group II-VI material may include at least one element from Group II and at least one element from Group VI, for example, ZnS, ZnSe, ZnSSe, ZnCdS, CdS, or CdSe. Similarly, a Group III-V material may include at least one element from Group III and at least one element from Group V, for example GaAs, GaP, GaAsP, InAs, InP, AlGaAs, or InAsP. Other dopants may also be included with these materials and combinations thereof, for example, transition metals such as Fe, Co, Te, Au, and the like.

As used herein, a “semiconductor” is given its ordinary meaning in the art, i.e., an element having semiconductive or semi-metallic properties (i.e., between metallic and non-metallic properties). An example of a semiconductor is silicon. Other non-limiting examples include elemental semiconductors, such as gallium, germanium, diamond (carbon), tin, selenium, tellurium, boron, or phosphorous. The semiconductor may be undoped or doped (e.g., p-type or n-type).

As used herein, a “single crystal” item (e.g., a semiconductor) is an item that has covalent bonding, ionic bonding, or a combination thereof throughout the item. Such a single crystal item may include defects in the crystal, but is distinguished from an item that includes one or more crystals, not ionically or covalently bonded, but merely in close proximity to one another.

The following U.S. provisional and utility patent application documents are incorporated herein by reference in their entirety for all purposes: Ser. No. 60/142,216, entitled “Molecular Wire-Based Devices and Methods of Their Manufacture,” filed Jul. 2, 1999; Ser. No. 60/226,835, entitled, “Semiconductor Nanowires,” filed Aug. 22, 2000; Ser. No. 10/033,369, entitled “Nanoscopic Wire-Based Devices and Arrays,” filed Oct. 24, 2001, published as Publication No 2002/0130353 on Sep. 19, 2002; Ser. No. 60/254,745, entitled, “Nanowire and Nanotube Nanosensors,” filed Dec. 11, 2000; Ser. No. 60/292,035, entitled “Nanowire and Nanotube Nanosensors,” filed May 18, 2001; Ser. No. 60/292,121, entitled, “Semiconductor Nanowires,” filed May 18, 2001; Ser. No. 60/292,045, entitled “Nanowire Electronic Devices Including Memory and Switching Devices,” filed May 18, 2001; Ser. No. 60/291,896, entitled “Nanowire Devices Including Emissive Elements and Sensors,” filed May 18, 2001; Ser. No. 09/935,776, entitled “Doped Elongated Semiconductors, Growing Such Semiconductors, Devices Including Such Semiconductors, and Fabricating Such Devices,” filed Aug. 22, 2001, published as Publication No. 2002/0130311 on Sep. 19, 2002; Ser. No. 10/020,004, entitled “Nanosensors,” filed Dec. 11, 2001, published as Publication No. 2002/0117659 on Aug. 29, 2002; Ser. No. 60/348,313, entitled “Transistors, Diodes, Logic Gates and Other Devices Assembled from Nanowire Building Blocks,” filed Nov. 9, 2001; Ser. No. 60/354,642, entitled “Nanowire Devices Including Emissive Elements and Sensors,” filed Feb. 6, 2002; Ser. No. 10/152,490, entitled, “Nanoscale Wires and Related Devices,” filed May 20, 2002; Ser. No. 10/196,337, entitled, “Nanoscale Wires and Related Devices,” filed Jul. 16, 2002, published as Publication No. 2003/0089899 on May 15, 2003; Ser. No. 60/397,121, entitled “Nanowire Coherent Optical Components,” filed Jul. 19, 2002; Ser. No. 10/624,135, entitled “Nanowire Coherent Optical Components,” filed Jul. 21, 2003; Ser. No. 60/524,301, entitled, “Nanoscale Arrays and Related Devices,” filed Nov. 20, 2003; Ser. No. 60/397,121, entitled “Nanowire Coherent Optical Components,” filed Dec. 11, 2003; Ser. No. 60/544,800, entitled “Nanostructures Containing Metal-Semiconductor Compounds,” filed Feb. 13, 2004; Ser. No. 10/347,121, entitled, “Array-Based Architecture for Molecular Electronics,” filed Jan. 17, 2003; Ser. No. 10/627,405, entitled “Stochastic Assembly of Sublithographic Nanoscale Interfaces,” filed Jul. 24, 2003; Ser. No. 10/627,406, entitled “Sublithographic Nanoscale Memory Architecture,” filed Jul. 24, 2003; Ser. No. 60/524,301, entitled “Nanoscale Arrays and Related Devices,” filed Nov. 20, 2003; Ser. No. 60/551,634, entitled “Robust Nanostructures,” filed Mar. 8, 2004; and a patent application entitled “Nanoscale Arrays, Robust Nanostructures, and Related Devices,” filed Nov. 22, 2004. The following International Patent Publication is incorporated herein by reference in their entirety for all purposes: Application Serial No. PCT/US00/18138, entitled “Nanoscopic Wire-Based Devices, Arrays, and Methods of Their Manufacture,” filed Jun. 30, 2000, published as Publication No. WO 01/03208 on Jan. 11, 2001; Application Serial No. PCT/US01/26298, entitled “Doped Elongated Semiconductors, Growing Such Semiconductors, Devices Including Such Semiconductors, and Fabricating Such Devices,” filed Aug. 22, 2001, published as Publication No. WO 02/17362 on Feb. 28, 2002; Application Serial No. PCT/US01/48230, entitled “Nanosensors,” filed Dec. 11, 2001, published as Publication No. WO 02/48701 on Jun. 20, 2002; Application Serial No. PCT/US02/16133, entitled “Nanoscale Wires and Related Devices,” filed May 20, 2002, published as Publication No. WO 03/005450 on Jan. 16, 2003.

### Example 1

This example illustrates cross point hysteretic resistance switches based on a core-shell nanowire-metal nanowire crossbar in which the core/shell nanowire core acts as one electrode contact, the shell, which can be controlled synthetically, functions as the storage medium, and the metal nanowire serves as the second electrode contact.

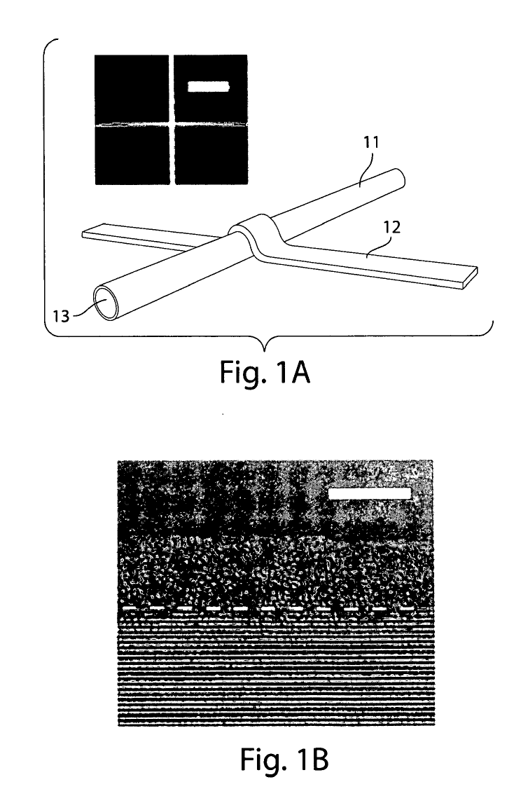

FIG. 1A shows a Si/a-Si core/shell nanowire (crystalline silicon/amorphous silicon) and a lithographically defined crossed metal nanowire. A single switch is formed at the cross point of a Si (11)/a-Si (13) core/shell nanowire and a metal nanowire (12). The inset is an SEM image of a Si/a-Si nanowire (horizontal) crossed Ag-metal nanowire (vertical) device; the scale bar is 1 micrometer. The core-shell nanowires used in this structure were synthesized in a two step chemical vapor deposition process developed previously, which involves (i) metal nanocluster-catalyzed Si nanowire core growth followed by (ii) homogeneous deposition of the amorphous Si shell.

The Si/a-Si core-shell nanowires were grown using methods similar to other core-shell heterostructure nanowire growth. The Si core was grown at 435° C. for 20 min using silane (2 sccm) and 100 ppm of diborane in helium (10 sccm) at 20 torr, yielding an axial growth rate of about 1 micrometers per minute. The a-Si shell was grown at 450° C. for 5 min at 15 torr using the same reactant flow rate. The growth rate of the a-Si shell was about 1 nm per minute. Growth of some of the nanowires that were used for control experiments omitted the shell growth step. The as-grown nanowires were dispersed in ethanol by sonication.

High-resolution transmission electron microscopy (HRTEM) imaging of the as-grown nanowire (FIG. 1B) shows core/shell structure with an ˜5 nm uniform amorphous silicon shell surrounding the single-crystal Si core and a sharp crystalline Si/a-Si interface. In FIG. 1B, the dashed line indicates the interface between core and shell. The scale bar is 5 nm. The HRTEM characterization (JEOL 2010F) was performed with the nanowires deposited on copper grids. The Si/a-Si nanowires were configured as cross point devices for electrical characterization in a hybrid bottom-up/top-down approach. First, the core/shell nanowires were assembled on a substrate using fluidic-based alignment and then Ni-metal contacts were defined at the nanowire ends; Ni was chosen as the contact metal because it readily forms ohmic junctions to Si nanowires. Second, an additional lithography step was used to define one or more crossed metal nanowires. In particular, the device fabrication was carried out by two-step electron beam (e-beam) lithography (Raith 150 Ebeam) after the nanowires were deposited on oxidized silicon or 125 micrometer polyimide (500-FPC, Kapton) substrates. The first lithography step defined the electrical contacts to the nanowires, followed by wet etching (buffered HF, 15 s), and thermal evaporation of Ni (60 nm thick). The devices were subsequently annealed at 350° C. for 60 seconds in forming gas (N₂/H₂, 90%/10%), (Heatpulse 610, Metron Technology) to facilitate better ohmic contacts to the Si core. Ag (60 nm) nanowires were then defined in the second e-beam lithography step and deposited above the a-Si shell without etching and annealing. For the 2×2 array fabrication, the nanowires were first flow-aligned. SEM imaging or e-beam writing on Kapton substrates used a layer of conductive polymer (ESPACER, Showa Denko) to avoid charging.

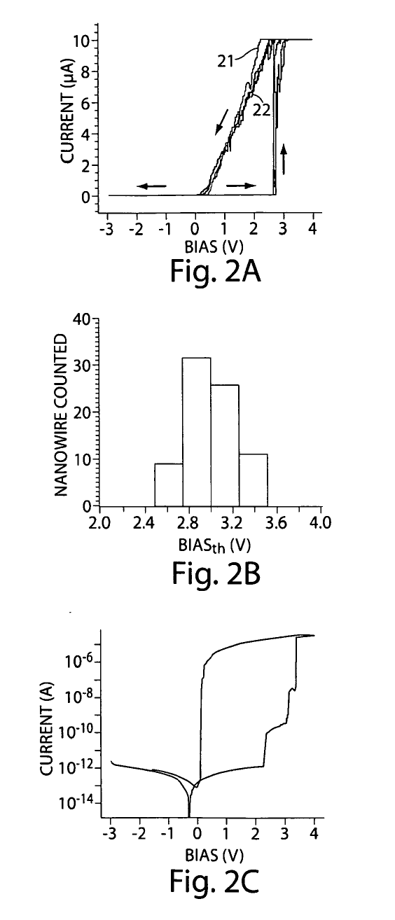

Representative current versus voltage (I-V) data obtained from a single Si/a-Si nanowire×Ag nanowire device (FIG. 2A) exhibits several important features. The arrows indicate the voltage-scanning direction. First, as the voltage was increased from 0 to 4 V, the current abruptly increased at ˜3 V. This abrupt transition point can be defined as the threshold voltage to switch the device from a high-resistance OFF state to a low-resistance ON state. Here voltage is defined as positive when the Ag nanowire is positively biased. Also, as the voltage was subsequently reduced to a negative threshold value (−3 V in this case) the device switched back to the high-resistance OFF state. In addition, the Si/a-Si nanowire×Ag nanowire devices exhibited intrinsic current rectification; that is, the crossed nanowire devices showed low conductance in the ON state when the applied voltage is negative (FIG. 2A). The devices remained in the ON state as long as the applied negative voltage did not cross the turn-off threshold of about −3 V.

This intrinsic rectification has not been observed previously for crossbar molecular structures, metal/a-Si/metal (M2M) or other metal/insulator/metal (MIM) devices. Current rectification is an attractive property, because it can minimize cross talk between individual elements in arrays and will be discussed further below. Also, switching between ON and OFF states was reproducible as exemplified by coincidence of initial cycle (lighter curve 21, FIG. 2A) and three subsequent cycles (darker curves 22, FIG. 2A). The reproducibility of the switching in the Si/a-Si nanowire×Ag nanowire structure was further confirmed by measurements on more than 80 devices. Notably, a histogram summarizing the threshold voltage from over 80 Si/a-Si nanowire×Ag nanowire devices (FIG. 2B) exhibited a relatively tight distribution with a mean±1 standard deviation of 3.0±0.5 V and an overall yield of 95%.

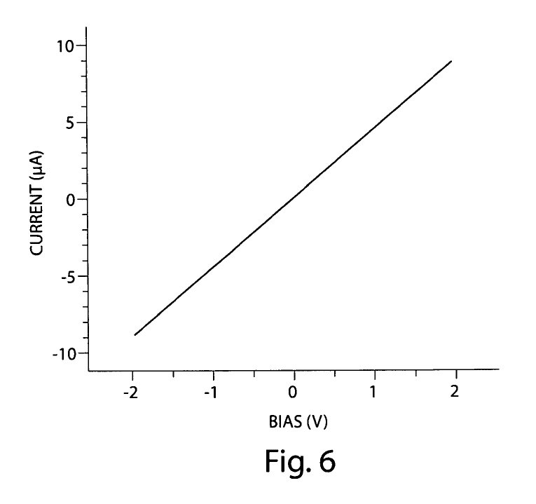

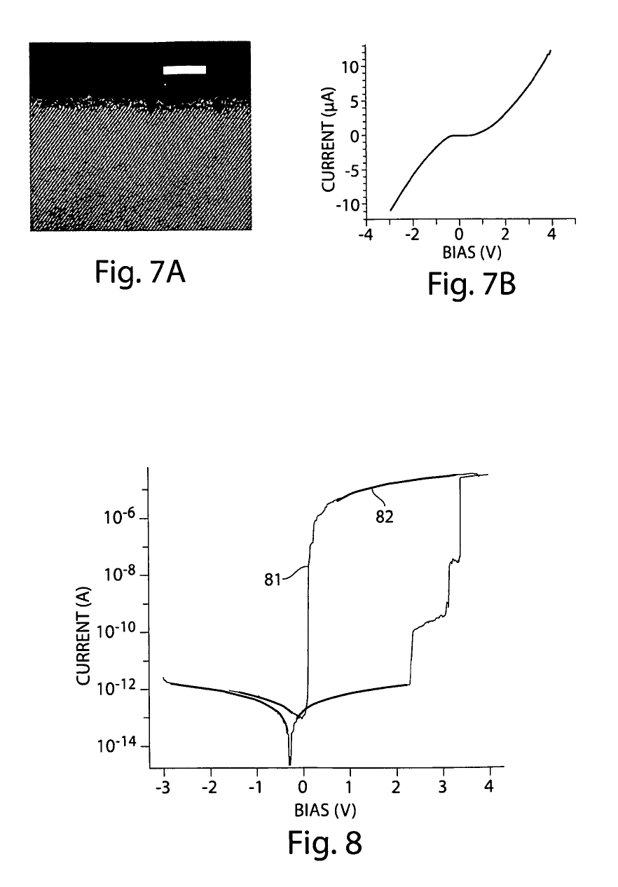

In addition, several other experiments were carried out to characterize basic crossed nanowire structure. I-V data recorded between two Ni contacts show linear behavior (FIG. 6), which shows current-voltage data recorded between two Ni contacts for a Si/a-Si nanowire. The linear behavior confirms that the Ni contacts to the nanowire are ohmic. Thus, there appears no barrier between Ni and Si/a-Si core/shell nanowires. Measurements made on Si nanowire×Ag nanowire structures (i.e., without the a-Si shell) show no switching or hysteresis (FIG. 7). FIG. 7A is a HRTEM image of a Si nanowire used in these experiments without the a-Si shell layer. The scale bar is 5 nm. FIG. 7B shows current-voltage data recorded between the ohmic (Ni) contact to the Si nanowire and the Ag nanowire electrode for a representative device. No switching was observed.

These control experiments demonstrate that the observed switching can be attributed to the Si/a-Si nanowire×Ag nanowire junction. Transport data recorded over a large dynamic range and plotted on log scale (FIG. 2C) highlight the large ON/OFF ratio, which can exceed 10⁶ for a range of read voltages. Current rectification can also be observed with this data, which is consistent with FIG. 2A; the rectification ratio obtained from the logarithmic data was >10⁶ at ±1.5 V. This figure shows the current vs. voltage cycle as in FIG. 2A, but plotted on logarithmic scale. The transition from OFF to ON state exhibited several steps (FIG. 2C) before the ON state was fully reached.

The measurement of the basic I-V curves, endurance cycles, and retention times test of the device were carried out in air with a probe station (TTP-4, Desert Cryogenics, Tucson, Ariz.), using either a home-built measurement setup with a current amplifier (DL instruments 1211, Ithaca, N.Y.) or a high-precision semiconductor analyzer (Agilent 4156C, Agilent Technologies, Palo Alto, Calif.). The temperature-dependence measurements were carried out under vacuum (<1˜10⁻⁴ torr). The nanosecond voltage pulses were generated with an Agilent 33220A function generator and the current signal recorded on a Tektronix TDS 3012 oscilloscope.

To probe further the Si/a-Si×Ag nanowire structures, the electrical transport characteristics as a function of the crossed junction size and temperature were investigated. First, current-voltage measurements made in a three-terminal geometry demonstrated that the intrinsic junction resistance in the ON state was approximately independent of the junction size as the metal width was reduced from 1000 to 20 nm (FIG. 3A). In particular, this figure shows the ON state resistance for devices with metal line widths of 20, 100, 500, and 1000 nm. The data were measured in a three-terminal configuration to eliminate the nanowire voltage drop. The inset is a SEM image of the device; the scale bar is 1 micrometer. In this figure, A and B are ohmic contacts to the Si/a-Si nanowire, and M is the crossed metal line. In the three terminal measurements, the current I flowed between the metal line (M) and the right ohmic contact (B), and the voltage V_{M-A} is measured between M and the left ohmic contact (A), such that V_{M-A} reflected the actual voltage drop at the Si/a-Si×M junction and not contributions from the nanowire series resistance. The on-resistance Rₒₙ was measured as V_{M-A}/I at V_{M-A}) 2 V in the on-state.

Constant junction resistance has been observed in previous studies of micron-scale M2M devices and attributed to the formation of a metal filament, which defines the ON-state resistance. It is believed that a similar mechanism (FIG. 3B) is consistent with this data, although filaments in these experiments were ≦20 nm in contrast to ˜0.5 micrometer size observed in M2M devices. In FIG. 3B, which is a schematic illustrating the OFF and ON states for the Si/a-Si/metal junctions, the gray dots represent the silver islands that form the conducting filament in the ON state. A consequence of the proposed filament model shown in FIG. 3B is that the current may be dominated by tunneling between the metal islands forming the filament (FIG. 3B) as the device was driven to ON and then back to OFF states. The step-like changes in log-scale data (e.g., FIG. 2C) as devices were turned on was consistent with the step-by-step filament formation as the metal is driven closer toward the core Si nanowire electrode. Quantitative fits of the data in FIG. 2C (FIG. 8) were consistent with this general model and tunneling appeared to dominate current as the device was stepwise turned ON and OFF.

In FIG. 8, the raw data is shown as 81 and fits in 82. A standard tunneling model in which the current through the Si/a-Si×M junction is assumed to be limited by tunneling of electrons between the last metal island and the SiNW core electrode was used: I=K sinh k(V−V₀), where K and k are constants depending on the tunneling barrier height Φ (Phi) and the distance s between the last metal island and the SiNW core, and Vₒ accounts for excess charges in the a-Si shell layer. The steps in the I-V data are consistent with the last metal island moving closer to the Si nanowire core.

Temperature-dependent current-voltage measurements were carried out to obtain further insight into the switching mechanism. Representative I-V curves obtained on a single Si/a-Si×Ag nanowire device as a function of temperature (FIG. 3C) showed that the switching characteristics may depend on temperature (FIG. 2D). The turn-ON threshold voltage increased from ˜3 to ˜4 V as the temperature was reduced from 350 to 50 K. The increase in turn-ON voltage may be due to the reduction of the Ag-ion mobility in the a-Si matrix, as reported previously in M/a-Si/M switching devices. The magnitude of the current remains roughly constant from 350 to 50 K, consistent with the tunneling model. Of greater significance, as the temperature is reduced below 250 K the current rectification was lost and a more conventional resistor-like behavior was observed in the ON state. Without wishing to be bound by any theory, qualitatively, these results can be explained within the context of the filament model as follows. Writing the device to the ON state at large positive biases resulted in the formation of a chain of metal islands that were assume to be trapped in the a-Si matrix with an average energy barrier height D (Phi) (FIG. 3D). This figure shows a schematic of barriers for the metal filament displacement in the a-Si adjacent to the SiNW core, where Φ (Phi) corresponds to the barrier height and the arrow indicates direction of metal displacement. Because hopping of the metal ions is a thermally activated process, it is possible for the metal ions to hop away from SiNW core at high temperatures and thereby yield a high-resistance state at small negative bias (the rectifying behavior). At sufficiently low temperatures, the filament is trapped in the ON state and does not exhibit rectification.

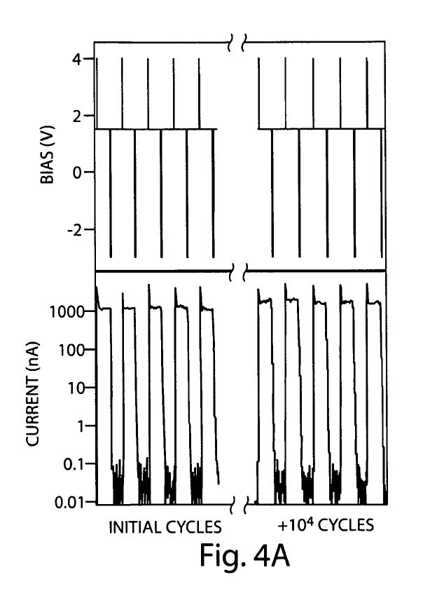

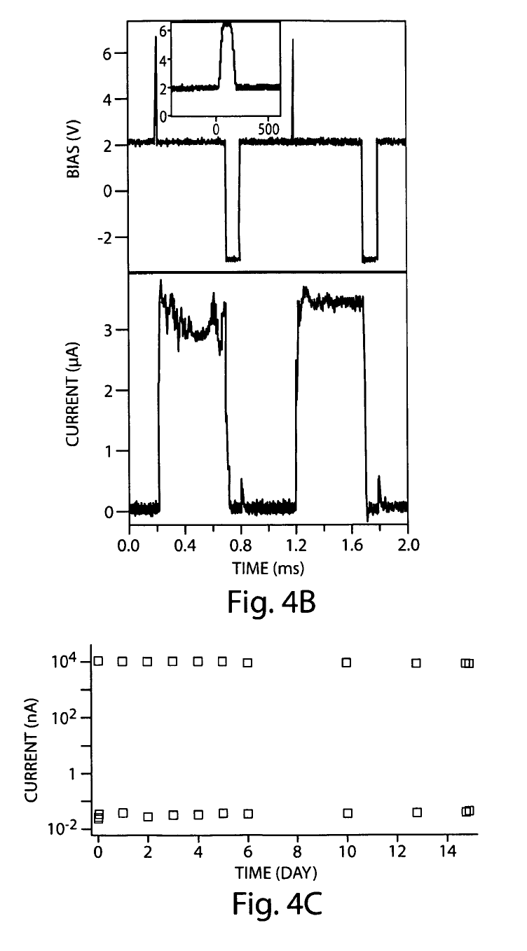

In addition, certain properties of the Si/a-Si×Ag nanowire devices relevant to their potential use as nonvolatile switch/memory elements were characterized. First, the switching robustness was determined by repeating a cycle consisting of write, read, erase, and read steps as shown in FIG. 4A where the write, read, and erase voltages were +4, +1.5, and −3 V, respectively. The current during the read step was 10⁻⁶ A in the ON and <10⁻¹⁰ A in the OFF state. It was found that the devices could be reliably switched between and read in ON and OFF states for at least approximately 10⁴ cycles without obvious degradation. In FIG. 4A, the top curve shows the applied bias sequence for erase and write pulses, and the bottom curve shows corresponding current response read at 1.5 V. The measured OFF state current is limited by the dynamic range of the current amplifier used. Similarly, FIG. 4B shows a writing speed test, where the upper curve shows sequence write and erase pulses, and the lower curve shows corresponding current response read at 2 V. The inset is a high-resolution measurement illustrating the temporal response of the write pulse.

The device-switching speed was tested using a similar but fast write pulse in the write-read-erase-read sequence. As shown in FIG. 3B, a 6.5 V write pulse of 100 ns could reproducibly turn on the device. Lower amplitude pulses, which are near the direct current switching threshold, were found to require a longer ca. microsecond duration to turn-on fully the devices. The retention time was also assessed in laboratory environment at room temperature. In these measurements, the device was disconnected from the power source after switching to ON or OFF states, and then the crossed nanowire resistance was periodically monitored. Notably, the data in FIG. 4C demonstrate that the device had less than 20% decay in ON state after two weeks and almost no change in OFF state, thus confirming the nonvolatile nature of the Si/a-Si×Ag nanowire devices. This figure shows the retention time test results for both ON and OFF states after writing or erasing the switch at +4 and −3 V, respectively. The current was read at 2 V.

The above results for the Si/a-Si×Ag nanowire devices in this example can be compared to molecular crossbar and M2M systems. Overall, the present endurance and retention times exceed those reported for molecular crossbar devices: 10⁴ versus 10-100 and >2 weeks versus several hours. The observed nanowire device endurance and speed are comparable to those of optimally formed planar micron-scale M2M structures, although retention times were shorter. Furthermore, the crossed nanowire devices can survive scanning electron microscopy (SEM) inspection (electron energy 3 keV) for at least 30 min without obvious degradation, suggesting potential as radiation hard structures.

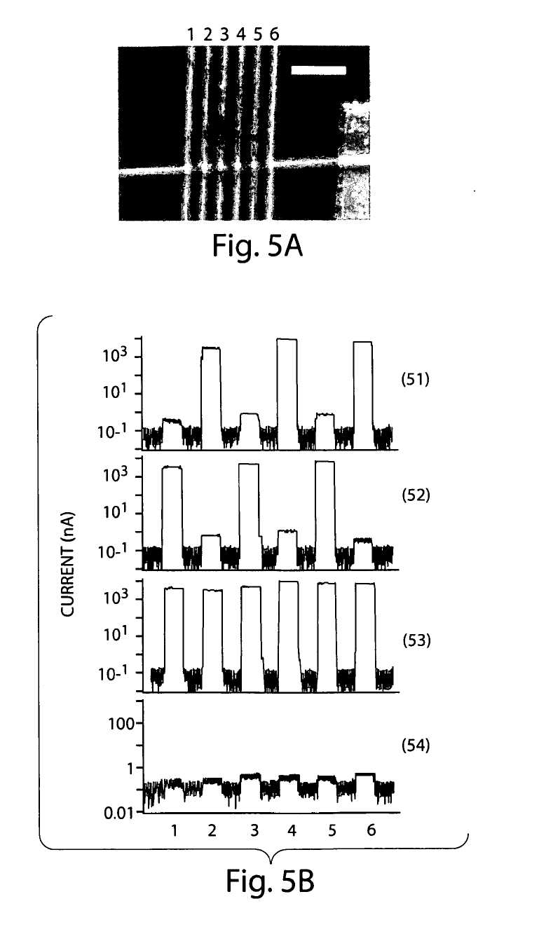

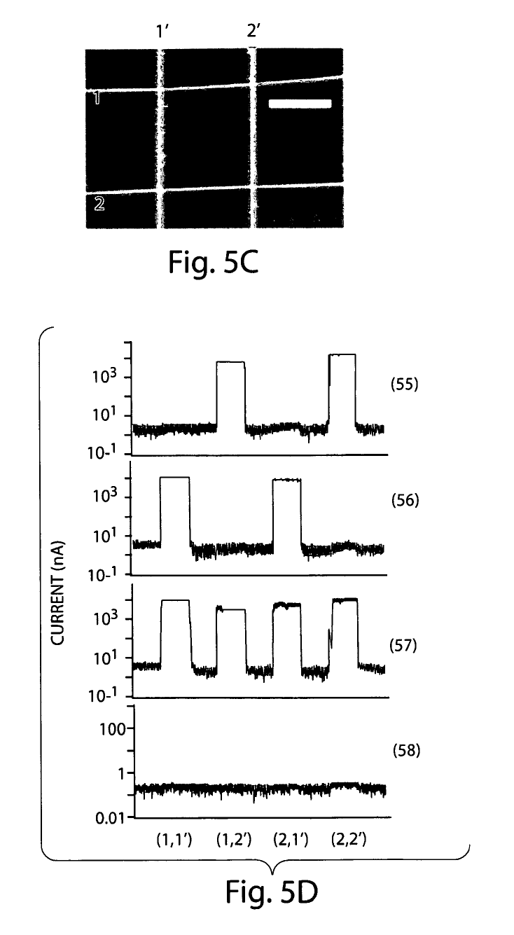

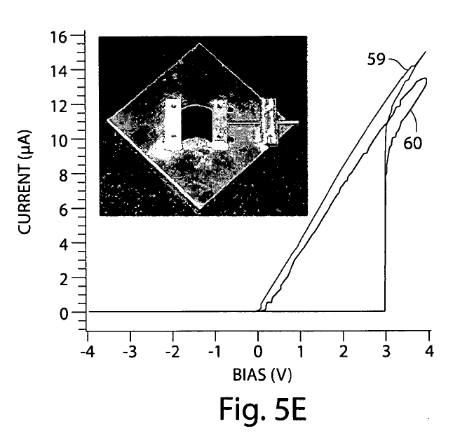

The scalability of the Si/a-Si×Ag nanowire device structure has been studied in 1D and 2D arrays. Relatively, dense 1D memory arrays were fabricated by crossing one Si/a-Si nanowire with n lithographically defined Ag nanowires (denoted 1×n) such as FIG. 5A, which shows a 1×6 array with Ag nanowire width of 30 and 150 nm spacing. The scale bar is 500 nm. Transport measurements (FIG. 5B) further show that it is possible to write or erase the six cross point switches to an arbitrary state (e.g., 000000, 111111, 101010, 010101 in FIG. 5B) and then read the state of n-switches without cross talk between elements during writing, reading or erasing. This figure shows the states of cross points 1-6 read at 2 V, as follows: (51)=010101, (52)=101010, (53)=111111, and (54)=000000. A basic 2×2 structure (FIG. 5C) was also fabricated to investigate whether the intrinsic rectification exhibited by Si/a-Si×Ag nanowire elements could eliminate cross talk in a 2D array. This figure is an SEM image of two Si/a-Si nanowires (horizontal) and two Ag nanowires (vertical) in a 2×2 array. The scale bar is 1 micrometer.

FIG. 5D shows that starting from the OFF state (0000), an arbitrary combination (e.g., 1111, 1010, 0101) of bits could be written into the array and then read out. This figure shows the state of the four cross points read at 2 V: (55)=0101, (56)=1010, (57)=1111, and (58)=0000. While the density of this test array is low, it should be possible to prepare much denser 2D arrays and even to extend the results to 3D layer-by-layer structures.

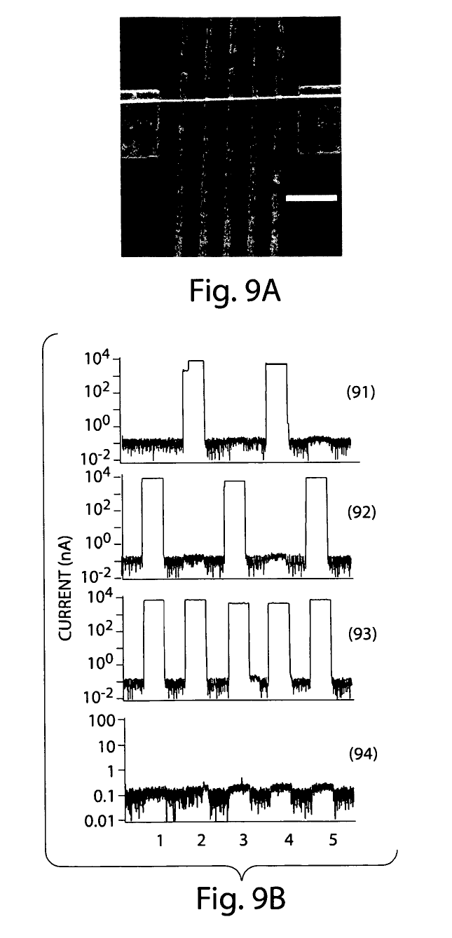

Also, this approach to Si nanowire-based crossbar switches is not limited to conventional crystalline substrate because the high-temperature nanowire synthesis is separate from the low-temperature fabrication process. To this end, Si/a-Si×Ag nanowire devices were assembled on flexible plastics and characterized their device properties. One-dimensional arrays fabricated on Kapton polyimide substrates (FIG. 9) showed that it is possible to write, read, and/or erase each of the five bits without cross talk. FIG. 9A shows an SEM image of one Si/a-Si nanowire with five crossed metal lines. The image was taken after spin coating the plastic substrate with one layer of conductive polymer (ESPACER, Showa Denko). The scale bar is 2 micrometers. FIG. 9B shows the states of the cross points 1-5 of the memory array sequentially read out by a 2 V bias after writing or erasing them to arbitrary combination with a 4 or a −3 V pulse, respectively. (91): 01010, (92): 10101, (93): 11111, (94): 00000.

Moreover, comparison of the switching cycles recorded when the device substrate was flat versus bent to a radius of curvature of 0.3 cm (FIG. 5E) showed little change in the threshold voltage and only a slight decrease (˜10%) in ON state current for the device in the bent configuration. The flexible plastic substrate was 1.2 cm×1.5 cm prior to measurement. I-V curves for the Si/a-Si×Ag nanowire device measured when the substrate was flat (59) and bent to a 0.3 cm radius of curvature (60). These latter results demonstrate the potential of these devices for development of flexible nonvolatile memory.

### Example 2

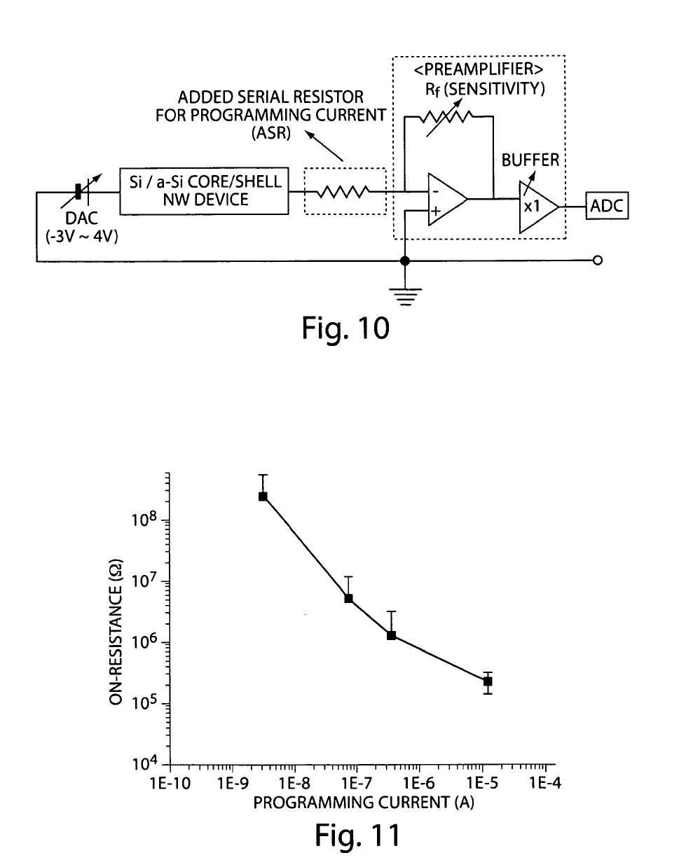

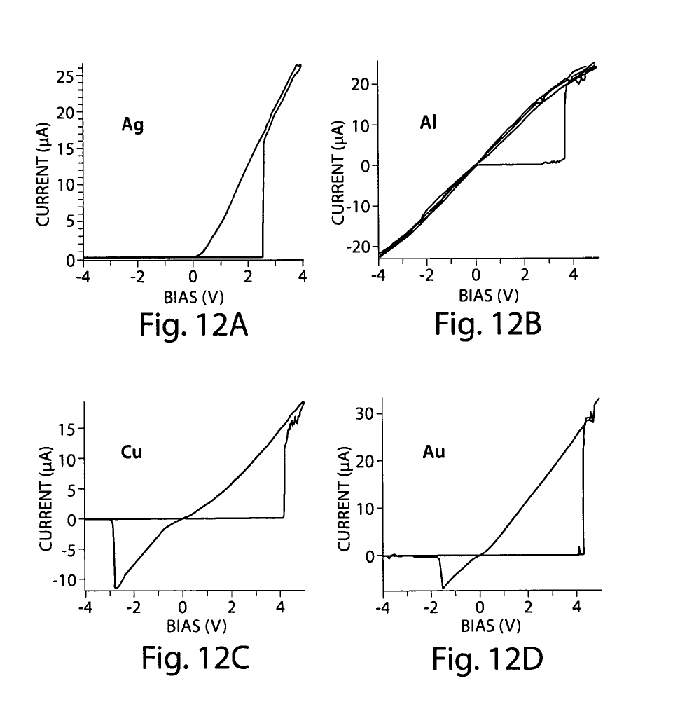

This example illustrates an example circuit useful for tuning the current applied to the device. In some cases, by tuning this programming circuit, multiple on-resistance states can be found in a single cross point, as is demonstrated in FIGS. 10-11 In FIG. 10, voltage is supplied using DAC (a digital-analog converter) to a nanowire device of the invention, e.g., one containing a Si/a-Si×Ag nanowire. In electrical communication with the Si/a-Si×Ag nanowire is a serial resistor, and a preamplifier unit, before ending with an ADC (an analog-digital converter). FIG. 11 shows that, by controlling the resistance, the current needed to reach the “ON” state can be controlled. However, it should be understood that these components are by way of example only, and in other embodiments, other methods may be used to control the current needed to reach the “ON” state.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A device, comprising:
an electrical crossbar array comprising at least two crossed conductors, at least one of which is a nanoscale wire comprising a core and at least one shell.

2-8. (canceled)

9. The device of claim 1, wherein at least a portion of the at least one shell comprises amorphous silicon.

10. The device of claim 1, wherein at least a portion of the at least one shell consists essentially of amorphous silicon.

11-22. (canceled)

23. A device, comprising:
an electrical crossbar array comprising at least two crossed wires crossing at a cross point, wherein the cross point exhibits intrinsic current rectification.

24-35. (canceled)

36. A method, comprising:
providing an electrical crossbar array comprising at least two crossed conductors crossing at a cross point;
causing the cross point to exhibit a first conductance by applying a positive voltage between the at least two crossed conductors; and
causing the cross point to exhibit a second conductance different from the first conductance by applying a negative voltage between the at least two crossed conductors.

37. The method of claim 36, wherein each of the two crossed conductors is a nanoscale wire.

38. The method of claim 36, wherein at least one of the crossed conductors comprises a semiconductor.

39. The method of claim 36, wherein at least one of the crossed conductors comprises silicon.

40. The method of claim 36, wherein the core comprises a crystal.

41. The method of claim 36, wherein the core comprises crystalline silicon.

42. The method of claim 36, wherein at least a portion of the at least one shell is amorphous.

43. The method of claim 36, wherein at least a portion of the at least one shell comprises amorphous silicon.

44. The method of claim 36, wherein at least one of the conductors comprises a metal.

45. The method of claim 36, wherein at least one of the conductors is positioned on a substrate.

46. (canceled)

47. The method of claim 36, wherein the crossbar array comprises a first set and second set of at least two parallel conductors.

48. A method, comprising an act of:
providing a nanoscale wire comprising a core and a shell at least partially surrounding the core; and
transporting metal ions from a source of metal into at least a portion of the shell.

49. The method of claim 48, wherein the source of metal is a metal electrode in electrical communication with the shell.

50-56. (canceled)

57. The method of claim 48, wherein the shell is amorphous.

58. The method of claim 48, wherein the metal ions are transported by applying a voltage between the source of metal and the core of the nanoscale wire.

59. (canceled)

60. The method of claim 48, further comprising altering a memory state defined by the nanoscale wire and the source of metal by transporting the metal ions into the shell.

61-75. (canceled)
